(19) United States
(12) Patent Application Publication
(10) Pub. No.: US 2013/0146908 A1
(43) Pub. Date: Jun. 13, 2013

(54) ILLUMINATION DEVICE

(71) Applicants: Chen-Chi Lin, Hsinchu County (TW); Po-Hsuan Chiang, New Taipei City (TW); Chang-Yen Wu, Taipei City (TW); Chun-Liang Lin, New Taipei City (TW)

(72) Inventors: Chen-Chi Lin, Hsinchu County (TW); Po-Hsuan Chiang, New Taipei City (TW); Chang-Yen Wu, Taipei City (TW); Chun-Liang Lin, New Taipei City (TW)

(73) Assignee: AU OPTRONICS CORPORATION, Hsinchu (TW)

(21) Appl. No.: 13/370,300

(22) Filed: Feb. 9, 2012

(30) Foreign Application Priority Data
Dec. 7, 2011 (TW) 100145077

(51) Int. Cl. H01L 51/52

(52) U.S. Cl. 257/98; 257/40; 257/E51.018

(57) ABSTRACT

An illumination device including a substrate, a first conductive layer, a second conductive layer, a self-illuminating layer, and a first auxiliary conductive pattern layer is provided. The first conductive layer and the second conductive layer are disposed on the substrate. The self-illuminating layer is located between the first conductive layer and the second conductive layer to define an illumination region on the substrate. The first auxiliary conductive pattern layer is in contact with the first conductive layer and has an impedance smaller than that of the first conductive layer. A ratio of a perimeter (um) of the first auxiliary conductive pattern layer occupied in the illumination region to an area (um²) of the illumination region is greater than about 0 and smaller than or equal to about 0.0262 (1/um).

### CROSS-REFERENCE TO RELATED APPLICATION

This application claims the priority benefit of Taiwan application serial no. 100145077, filed on Dec. 7, 2011. The entirety of the above-mentioned patent application is hereby incorporated by reference herein and made a part of this specification.

### BACKGROUND OF THE DISCLOSURE

1. Field of the Invention

The document relates to an illumination device, and particularly to a self-illuminating type illumination device.

2. Description of Related Art

Organic electroluminescent devices have been considered a dominant flat panel display in the future because of their desirable qualities of compactness, self-luminescence, low power consumption, no need of backlight source, no viewing angle limitation, and high response speed. In addition, a passive organic electroluminescent device can be fabricated on a thin, light, and flexible substrate so as to be suitable for the lighting application. Generally, if the light emitting efficiency of the organic electroluminescence device is improved to a level greater than 100 Lm/W and the color rendering index thereof is greater than about 80, the organic electroluminescence device is predetermined to be capable of replacing the conventional illumination source. Accordingly, the organic electroluminescence device would play an important role in the future lighting device.

However, the light emitting uniformity of the organic electroluminescence device is usually deteriorated with the increasing of the size. Therefore, it is still difficult to fabricate a desirable large sized organic electroluminescence device for the lighting application.

### SUMMARY OF THE DISCLOSURE

In one aspect is directed to an illumination device having uniformed light emitting effect and desirable light emitting efficiency.

In another aspect provides an illumination device including a substrate, a first conductive layer, a second conductive layer, a self-illuminating layer, and a first auxiliary conductive pattern layer. The first conductive layer and the second conductive layer are disposed on the substrate. The self-illuminating layer is disposed between the first conductive layer and the second conductive layer to define an illumination region on the substrate. The first auxiliary conductive pattern layer is in contact with the first conductive layer. The first auxiliary conductive pattern layer has an impedance smaller than that of the first conductive layer. A ratio of a perimeter (um) of the first auxiliary conductive pattern layer occupied in the illumination region to an area (um²) of the illumination region is greater than 0 and smaller than or equal to 0.0262 (1/um).

In an embodiment of the disclosure, the first auxiliary conductive pattern layer is disposed at a side of the first conductive layer adjacent to the self-illuminating layer.

In an embodiment of the disclosure, the first auxiliary conductive pattern layer is disposed at a side of the first conductive layer away from the self-illuminating layer.

In an embodiment of the disclosure, the first auxiliary conductive pattern layer includes a plurality of strip patterns. In one instance, the stripe patterns are connected to form a mesh.

In an embodiment of the disclosure, the first auxiliary conductive pattern layer includes a plurality of block patterns separated from each other.

In an embodiment of the disclosure, the ratio of the perimeter (um) of the first auxiliary conductive pattern layer occupied in the illumination region to the area (um²) of the illumination region is substantially equal to 0.022 (1/um).

In an embodiment of the disclosure, the illumination device further includes a second auxiliary conductive pattern layer in contact with the second conductive layer. The second auxiliary conductive pattern layer has an impedance smaller than that of the second conductive layer. A ratio of a perimeter (um) of the second auxiliary conductive pattern layer occupied in the illumination region to the area (um²) of the illumination region is greater than 0 and smaller than or equal to 0.0262 (1/um). The second auxiliary conductive pattern layer includes a plurality of stripe patterns. In one instance, the stripe patterns can be connected to form a mesh. The second auxiliary conductive pattern layer includes a plurality of block patterns separated from each other. In an embodiment of the disclosure, the ratio of the perimeter (um) of the second auxiliary conductive pattern layer occupied in the illumination region to the area (um²) of the illumination region is substantially equal to 0.022 (1/um).

In an embodiment of the disclosure, the first conductive layer is disposed at a side of the self-illuminating layer adjacent to the substrate and the second conductive layer is located at a side of the self-illuminating layer away from the substrate.

In an embodiment of the disclosure, the first conductive layer is disposed at a side of the self-illuminating layer away from the substrate and the second conductive layer is located at a side of the self-illuminating layer adjacent to the substrate.

In an embodiment of the disclosure, a material of the self-illuminating layer includes an organic light emitting material.

In an embodiment of the disclosure, the illumination device further includes a light extraction layer disposed at a side of the substrate away from the self-illuminating layer.

In an embodiment of the disclosure, the illumination device further includes a protection material, wherein the first conductive layer, the self-illuminating layer, and the second conductive layer are located between the protection material and the substrate.

In view of the above, the illumination device of the disclosure improves the electric current transmission of the conductive layer by the configuration of the auxiliary conductive pattern layer, so that a uniformed electric field can be formed in the conductive layer and the illumination device has desirable light emitting uniformity. In addition, in the illumination device of the invention, the layout of the auxiliary conductive pattern layer is designed according to the area of the illumination region, such that the light emitted from the illumination device is not restricted inside the illumination device and the required light extraction efficiency can be achieved.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 through FIG. 5 is respectively a schematic cross-sectional view illustrating an illumination device according to an exemplary embodiment.

FIG. 6 is a partially enlarged schematic diagram of the illumination device depicted in FIG. 1.

FIG. 7 is a schematic diagram illustrating a layout of the auxiliary conductive pattern layer according to the exemplary embodiment.

FIG. 8 through FIG. 10 is respectively a schematic diagram illustrating a type of the layout of the auxiliary conductive pattern layer inside the illumination region.

### DESCRIPTION OF EMBODIMENTS

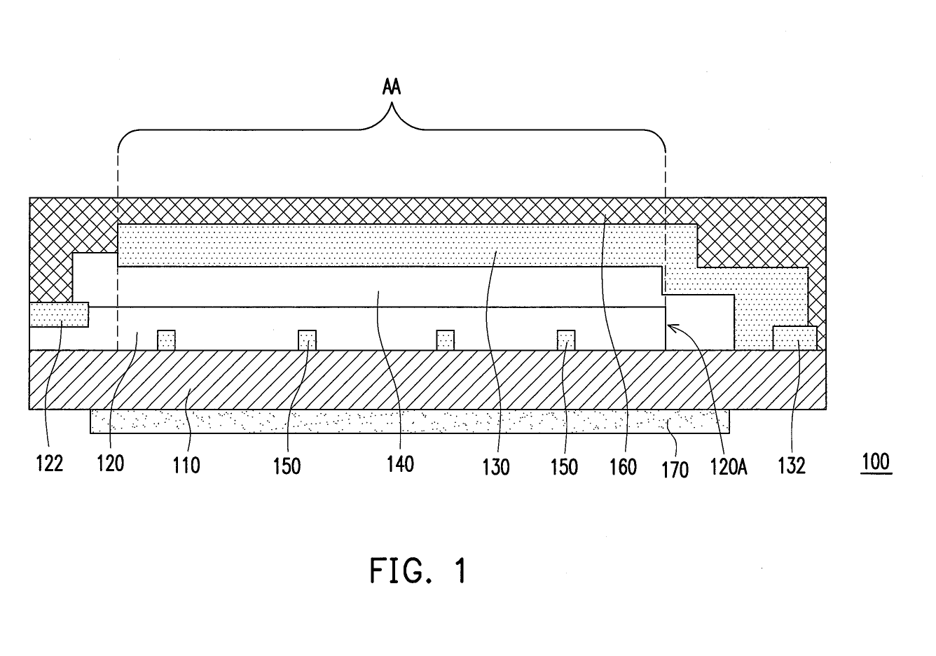

FIG. 1 through FIG. 5 is respectively a schematic cross-sectional view illustrating an illumination device according to an exemplary embodiment. Referring to FIG. 1, an illumination device 100 includes a substrate 110, a first conductive layer 120, a second conductive layer 130, a self-illuminating layer 140, a first auxiliary conductive pattern layer 150, a protection material 160, and a light extraction layer 170. The first conductive layer 120, the second conductive layer 130, the self-illuminating layer 140, the first auxiliary conductive pattern layer 150, the protection material 160, and the light extraction layer 170 are disposed on the substrate 110.

The first conductive layer 120, the second conductive layer 130, and the self-illuminating layer 140 are stacked on a same side of the substrate 110 which is the first surface of the substrate 110 (or namely the inner surface of the substrate 110) and the self-illuminating layer 140 is disposed between the first conductive layer 120 and the second conductive layer 130 to define an illumination region AA on the substrate 110. In the embodiment, the material of the self-illuminating layer 140 can include, but not be restricted to, an organic light emitting material. In specific, any material capable of emitting light by itself can be used to fabricate the self-illuminating layer 140. When energy such as an electric current is applied to the illumination device 100, the electric current can flow between the first conductive layer 120 and the second conductive layer 130, which achieves the recombination of the electric holes and the electrons in the self-illuminating layer 140 so as to emit light. Herein, light with different colors can be generated based on the characteristics of the self-illuminating layer 140 for providing the required light emitting effect.

For transmitting the corresponding electric current to the first conductive layer 120 and the second conductive layer 130, the illumination device 100 can be configured with the first electrode 122 in contact with the first conductive layer 120 and the second electrode 132 in contact with the second conductive layer 130 for connecting to an external electric power. Furthermore, based on the function of the self-illuminating layer 140, the first electrode 122 and the second electrode 132 can be respectively an anode and a cathode, or a cathode and an anode. In other words, one of the first conductive layer 120 and the second conductive layer 130 can be an anode conductive layer while the other is a cathode conductive layer. In an alternate embodiment, the external electric power can be directly connected to the first conductive layer 120 and the second conductive layer 130, which means that the first electrode 122 and the second electrode 132 can be omitted.

In one instance, the self-illuminating layer 140 generally includes a hole injection layer, a hole transmitting layer, a light emitting layer, an electron transmitting layer, and an electron injection layer sequentially stacked (not shown). In an alternate embodiment, the self-illuminating layer 140 includes a hole transmitting layer, a light emitting layer, and an electron transmitting layer sequentially stacked (not shown), or includes a hole injection layer, a light emitting layer, and an electron injection layer sequentially stacked (not shown). The first conductive layer 120 can be deemed as the anode conductive layer and the first electrode 122 can be deemed as the anode when the first conductive layer 140 contacts the hole injecting layer or the hole transmitting layer of the self-illuminating layer 140. Now, the second conductive layer 130 is in contact with the electron injecting layer or the electron transmitting layer of the self-illuminating layer 140 and is deemed as the cathode conductive layer while the second electrode 132 is deemed as the cathode. Alternatively, the first conductive layer 120 and the first electrode 122 can be deemed as the cathode conductive layer and the cathode and the second conductive layer 130 and the second electrode 132 can be deemed as the anode conductive layer and the anode when the stacking sequence of the material layers in the self-illuminating layer 140 are inversed. Accordingly, the anode and the cathode in the illumination device 100 can be determined by the stacking sequence of the material layers in the self-illuminating layer 140 and not particularly restricted.

In the present embodiment, the two sides of the self-illuminating layer 140 are configured with the first conductive layer 120 and the second conductive layer 130, respectively. Therefore, for emitting the light emitted outward from the self-illuminating layer 140, at least one of the first conductive layer 120 and the second conductive layer 130 has light transparency. In the embodiment, the first conductive layer 120 is, for example, fabricated by a transparent conductive material. It is for sure that the invention should not be construed as limited thereto. In other embodiments, the second conductive layer 130 can be selectively fabricated by the transparent conductive material. Accordingly, the illumination device 100 can emit light from the side of the first conductive layer 120 to have the single-side light emitting function or can emit light from both of the side of the first conductive layer 120 and the side of the second conductive layer 130 to have the dual-side light emitting function.

It is noted that the impendence of the transparent conductive material is not as satisfactory as the metal material for having desirable light transparency. Particularly, the area of the illumination region AA of the illumination device 100 increases, the sheet impedance of the first conductive layer 120 increases. Now, energy such as the voltage in the first conductive layer 120 is unevenly distributed such that the energy transmitted to the self-illuminating layer 140 from the first conductive layer 120 is not uniformed, which results in the uneven light emitting effect of the self-illuminating layer 140. In the present embodiment, the impedance of the first conductive layer 120 can be obtained because the material of the first conductive layer 120 is known. Herein, based on the Ohmic's law, the relationship between the voltage of the first conductive layer 120 and the electric current transmitted in the first conductive layer 120 can be estimated. For example, when the distribution of the voltage of the first conductive layer 120 in different areas is uneven and the impedance of the first conductive layer 120 is consistent, the electric current distributed in the first conductive layer 120 can be uneven in different areas, which results in that the light emitting intensity of the self-illuminating layer 140 is unevenly distributed. Therefore, the first auxiliary conductive pattern layer 150 is disposed in the illumination device 100 according to the embodiment, wherein the first auxiliary conductive pattern layer 150 is in contact with the first conductive layer 120 and the impedance of the first auxiliary conductive pattern layer 150 is substantially smaller than the impedance of the first conductive layer 120. As such, the sheet impedance of the first conductive layer 120 can be improved to render the illumination device 100 having uniformed light emitting effect.

The protection material 160 can be selectively disposed in the illumination device 100 for protecting the components such as the first conductive layer 120, the second conductive layer 130, and the self-illuminating layer 140. The protection material 160 can be a protection substrate, a protection layer, or a protection film in contact with the second conductive layer 130, and alternately, the protection material 160 can be a structure with particular shape separated from the second conductive layer 130 by a distance. Namely, the protection material 160 can be formed on the second conductive layer 130 by a film deposition process, a coating process, or an adhering process. Alternately, the protection material 160 can be assembled to the substrate 110 for sealing the first conductive layer 120, the second conductive layer 130, and the self-illuminating layer 140.

Furthermore, the illumination device 100 further has the light extraction film 170 for achieving the improved light extracting efficiency. In this embodiment, the light emitted from the illumination device 100 is emitted outward after passing through the transparent first conductive layer 120 located at a side of the self-illuminating layer 140 adjacent to the substrate 110, i.e. the transparent first conductive layer 120 is located at the first surface of the substrate 110 (or namely the inner surface thereof). The light extraction film 170 can be disposed at a side of the substrate 110 away from the self-illuminating layer 140 which is the second surface of the substrate 110 (or namely the outer surface thereof), such that the total internal reflection effect can be restrained during the light passes through the substrate 110. In other embodiments, the light extraction film 170 can be disposed at a side of the protection material 160 away from the self-illuminating layer 140, i.e. the second surface (or namely the outer surface) of the protection material 160 when the second conductive layer 130 is designed as a light transparent component. The light extraction layer 170 can be disposed at the light emitting side of the illumination device 100 to reduce the total internal reflection effect at the interface which restricts the light extraction efficiency during the light emits to the external environment (such as the air) from the illumination device 100.

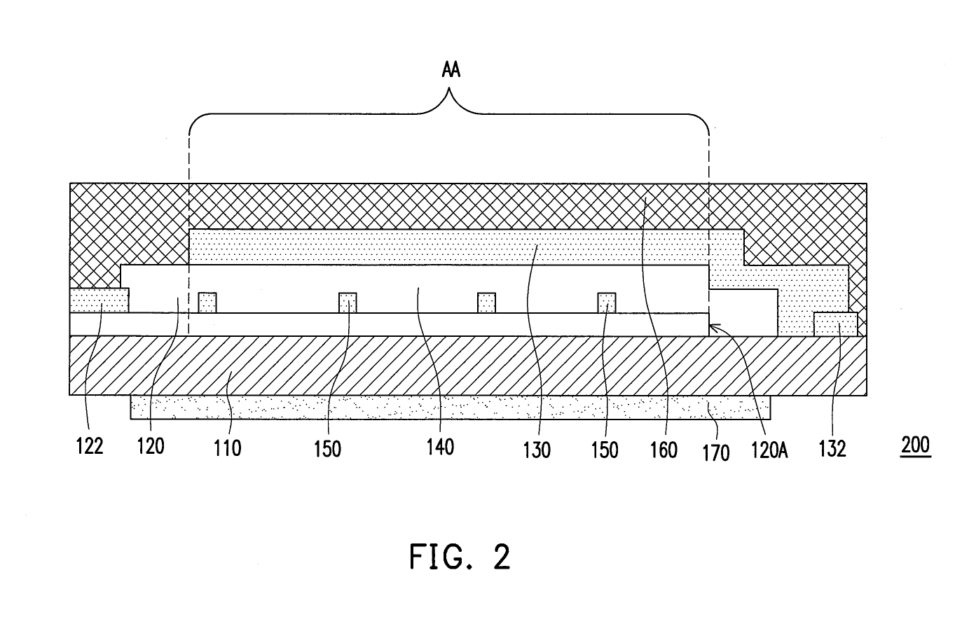

It is noted that the design of the illumination device 100 is not restricted to the foregoing descriptions. With reference to FIG. 2, the illumination device 200 is substantially the same as the illumination device 100, and therefore the reference numbers of the same components in these embodiments are identical. The difference between the illumination device 200 and the illumination device 100 mainly lies in that the first auxiliary conductive pattern layer 150 of the illumination device 200 is located between the self-illuminating layer 140 and the first conductive layer 120. It is noted that the disposition sequence of the first auxiliary conductive pattern layer 150 and the first conductive layer 120 is not particularly restricted in the disclosure, wherein the first auxiliary conductive pattern layer 150 and the first conductive layer 120 can be disposed in an arbitrary sequence between the self-illuminating layer 140 and the substrate 110.

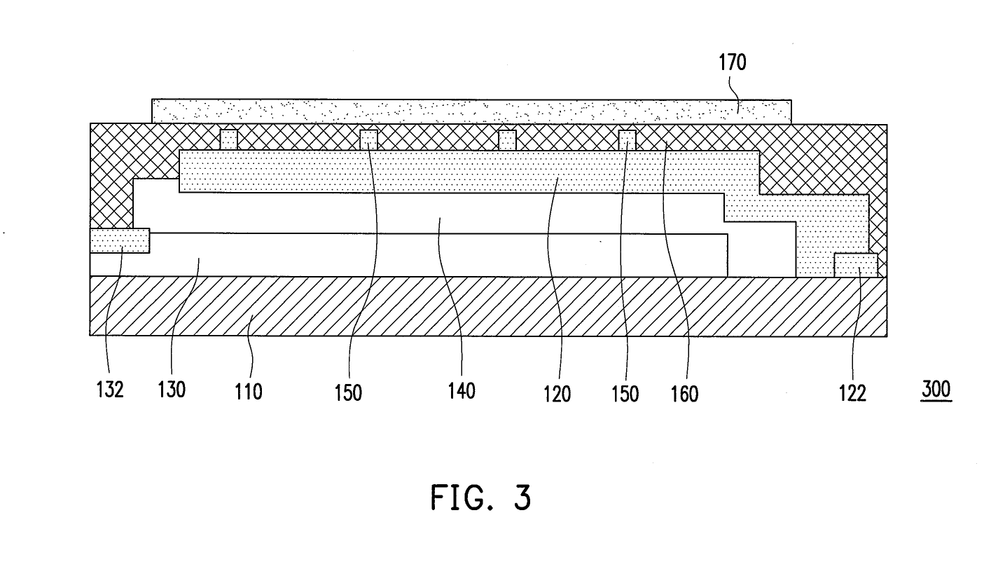

With reference to FIG. 3, the illumination device 300 is substantially the same as the illumination device 100, and therefore the reference numbers of the same components in these embodiments are identical. The difference between the illumination device 300 and the illumination device 100 mainly lies in that the first conductive layer 120 of the illumination device 300 is located between the self-illuminating layer 140 and the protection material 160 and the second conductive layer 130 is located between the self-illuminating layer 140 and the substrate 110. In addition, the light extraction layer 170 of the illumination device 300 is, for instance, located at a side of the protection material 160 away from the first conductive layer 120, i.e. the second surface (or namely the outer surface) of the protection layer 160.

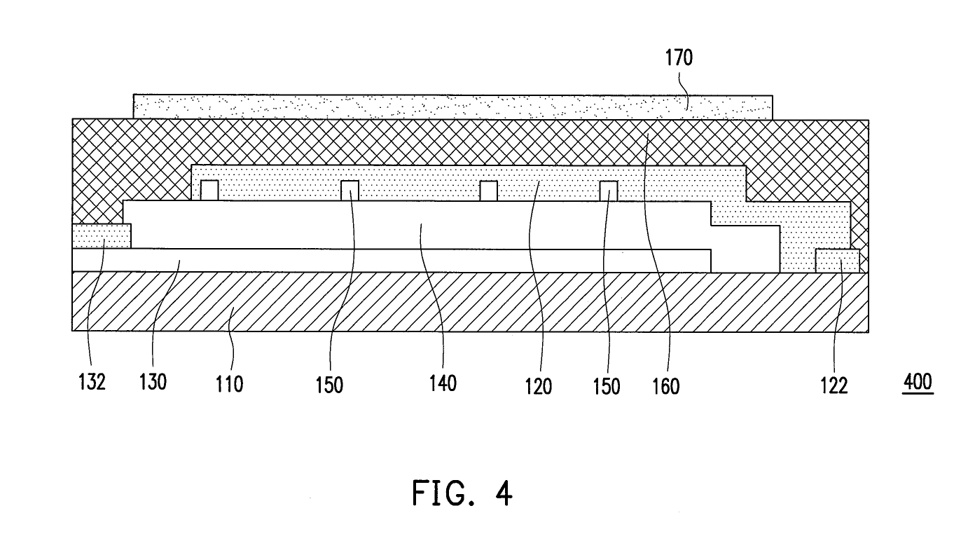

That is to say, in the embodiment depicted in FIG. 3, the second conductive layer 130, the self-illuminating layer 140, and the first conductive layer 120 are stacked sequentially outward from the substrate 110. Now, the first auxiliary conductive pattern layer 150 can be located at a side of the first conductive layer 120 away from the self-illuminating layer 140, i.e. the first auxiliary conductive pattern layer 150 is located between the first conductive layer 120 and the first surface (or namely the inner surface) of the protection layer 160. Alternately, as shown in the illumination device 400 depicted in FIG. 4, the first auxiliary conductive pattern layer 150 can be located at a side of the first conductive layer 120 adjacent to the self-illuminating layer 140, i.e. the first auxiliary conductive pattern layer 150 is located between the first conductive layer 120 and the self-illuminating layer 140.

In the embodiments illustrated in FIG. 3 and FIG. 4, the illumination device 300 and the illumination device 400 can emit light from the protection material 160 to have the single-side light emitting function. Moreover, the illumination device 300 and the illumination device 400 can have the dual-side light emitting function when the second conductive layer 130 is fabricated by the transparent conductive material. According to the descriptions of the foregoing embodiments, the configuration of the first auxiliary conductive pattern layer 150 is conducive to improve the light emitting uniformity of the illumination device 300 and the illumination device 400.

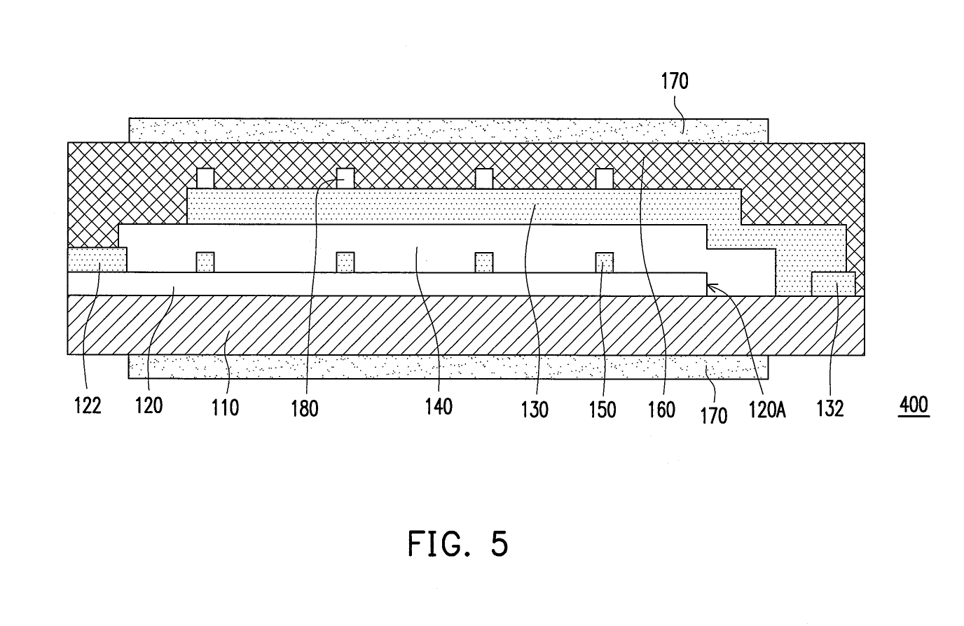

In another embodiment, as shown in the illumination device 500 depicted in FIG. 5, a second auxiliary conductive pattern layer 180 can further be configured in the illumination device 500 when the first conductive layer 120 and the second conductive layer 130 are both fabricated by the transparent conductive material, wherein the second auxiliary conductive pattern layer 180 is in contact with the second conductive layer 130. The second auxiliary conductive pattern layer 180 can be selectively disposed at a side of the second conductive layer 130 away from the self-illuminating layer 140, which is similar to the disposition of the first auxiliary conductive pattern layer 150 depicted in FIG. 3. Alternately, the second auxiliary conductive pattern layer 180 can be selectively disposed at a side of the second conductive layer 130 adjacent to the self-illuminating layer 140, which is similar to the disposition of the first auxiliary conductive pattern layer 150 depicted in FIG. 4. Now, the first auxiliary conductive pattern layer 150 can be selectively disposed at a side of the first conductive layer 120 away from the self-illuminating layer 140, which is similar to the disposition of the first auxiliary conductive pattern layer 150 depicted in FIG. 1. Alternately, the first auxiliary conductive pattern layer 150 can be selectively disposed at a side of the first conductive layer 120 adjacent to the self-illuminating layer 140, which is similar to the disposition of the first auxiliary conductive pattern layer 150 depicted in FIG. 2. Accordingly, the structure illustrated in FIG. 5 can be modified into four variants and these variants are described in the following descriptions.

Furthermore, a light extraction layer 170 can be disposed at a side of the protection material 160 away from the second conductive layer 130, i.e. the second surface (or namely the outer surface) of the protection material 160, and another light extraction layer 170 can be disposed at a side of the substrate 110 away from the first conductive layer 120, i.e. the second surface (or namely the outer surface) of the substrate 110.

Consequently, the disposition sequence of the auxiliary conductive pattern layer and the conductive layer are not particularly restricted in the disclosure. Merely the auxiliary conductive pattern layer is in contact with the conductive layer can the electric current transmission of the conductive layer be improved to make the illumination device has uniformed light emitting effect. Certainly, the above-mentioned embodiments are merely exemplary and should not be construed as limitations to this disclosure. Notably, the impedance of the auxiliary conductive pattern layer is substantially smaller than the impedance of the conductive layer in the embodiments. The auxiliary conductive pattern layer can have a single layer structure or a multi-layers structure and a material of the auxiliary conductive pattern layer can be metal, alloy, or the material having low impedance.

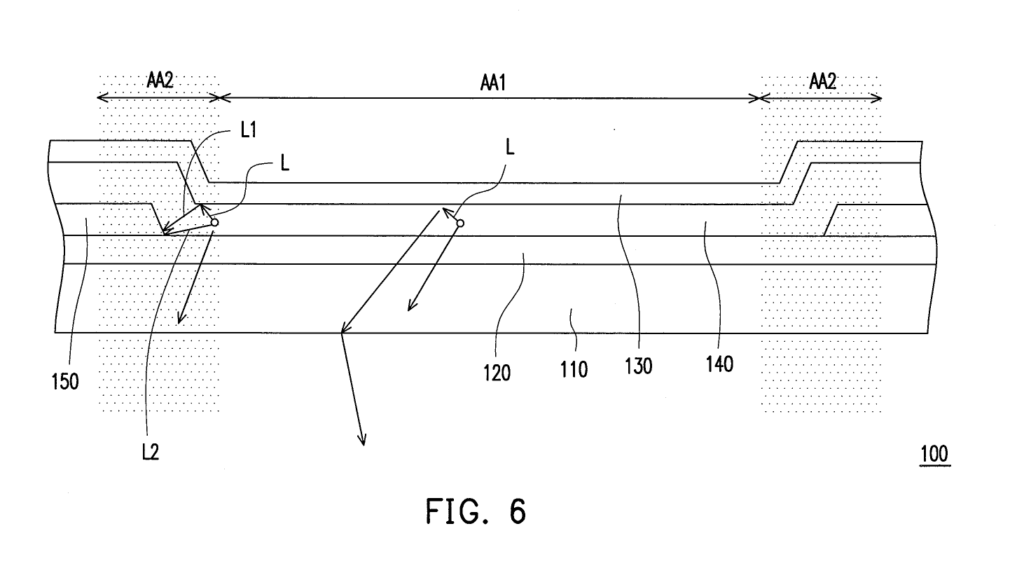

It is known that the materials such as metal or alloy have poor light transparency and high reflectance. Under the disposition of the first auxiliary conductive pattern layer 150, the light emitting effect of the illumination device 100 depicted in the aforesaid embodiment can be schematically shown in FIG. 6. Referring to FIG. 6 which is a partially enlarged schematic diagram of the illumination device 100 depicted in FIG. 1, the light L emitted from the self-illuminating layer 140 can emit toward various directions. The light L can be reflected by the second conductive layer 130 when the material of the second conductive layer 130 is made of the conductive materials having reflective property such as metal and the reflected light L can emit toward the substrate 110. Now, the illumination device 100 has the single-side light emitting design, which means that the light emitting surface of the illumination device 100 is the outer surface of the substrate 110.

According to those depicted in FIG. 6, the light L1 reflected by the second conductive layer 130 and the light L2 directly emitted from the self-illuminating layer 140 can irradiate on the first auxiliary conductive pattern layer 150 made of metal material. Herein, the light L1 and the light L2 are reflected by the first auxiliary conductive pattern layer 150 and can not pass through the first auxiliary conductive pattern layer 150. Accordingly, when the light emitting effect of the illumination device 100 is observed from the outer surface of the substrate 110, a relative brighter first illumination region AA1 and a relative darker second illumination region AA2 can be observed, wherein the first illumination region AA1 is where the first auxiliary conductive pattern layer 150 is not located and the second illumination region AA2 is wherein the periphery of the first auxiliary conductive pattern layer 150 is located. That is to say, the amount of the light emitted outward the substrate 110 in the second illumination region AA2 is less than the amount of the light emitted outward the substrate 110 in the first illumination region AA1. In specific, the illumination region AA defined on the substrate 110 by disposing the self-illuminating layer 140 between the first conductive layer 120 and the second conductive layer 130 includes the first illumination region AA1 and the second illumination region AA2.

As shown in FIG. 6, the larger the area of the second illumination region AA2, the worse the light extraction efficiency. For achieving desirable light extraction efficiency, the area of the second illumination region AA2 is, preferably reduced. The reducing of the area of the second illumination region AA2 means that the perimeter of the first auxiliary conductive pattern layer 150 has to be reduced. In the embodiment, the reducing of the perimeter of the first auxiliary conductive pattern layer 150 can be achieved by reducing the disposition area of the first auxiliary conductive pattern layer 150 or modifying the outline of the first auxiliary conductive pattern layer 150. However, the reducing of the area of the first auxiliary conductive pattern layer 150 restrains the auxiliary effect provided by the first auxiliary conductive pattern layer 150 and the energy such as the voltage in the first conductive layer 120 can be unevenly distributed, such that the energy received by the self-illuminating layer 140 is not uniformed, which results in the uneven light emitting effect. In the present embodiment, the impedance of the first conductive layer 120 can be obtained because the material of the first conductive layer 120 is known. Herein, based on the Ohmic's law, the relationship between the voltage of the first conductive layer 120 and the electric current transmitted in the first conductive layer 120 can be estimated. For example, when the distribution of the voltage of the first conductive layer 120 in different areas is uneven and the impedance of the first conductive layer 120 is uniformed, the electric current distributed in the first conductive layer 120 can be uneven in different areas so that the light emitting intensity of the self-illuminating layer 140 is unevenly distributed. Consequently, the layout of the second illumination region AA1 (i.e. the pattern design of the first auxiliary conductive pattern layer 150) deeply influences on the light emitting effect of the illumination device 100. The effect of the auxiliary conductive pattern layer described herein can be observed in any of the embodiments depicted in FIG. 2 through FIG. 5.

Accordingly, for achieving desirable light emitting effect, several layout designs of the auxiliary conductive pattern layer in the illumination region are provided in the following based on the spirit of the invention. The following descriptions are merely exemplarily provided and are by no means to be construed as limitations of the spirit and the scope of the invention. In addition, the layout mentioned in the following can be applied to the design of any of the first auxiliary conductive pattern layer 150 and the second auxiliary conductive pattern layer 180 or applied to both of the first auxiliary conductive pattern layer 150 and the second auxiliary conductive pattern layer 180 in the foregoing embodiments.

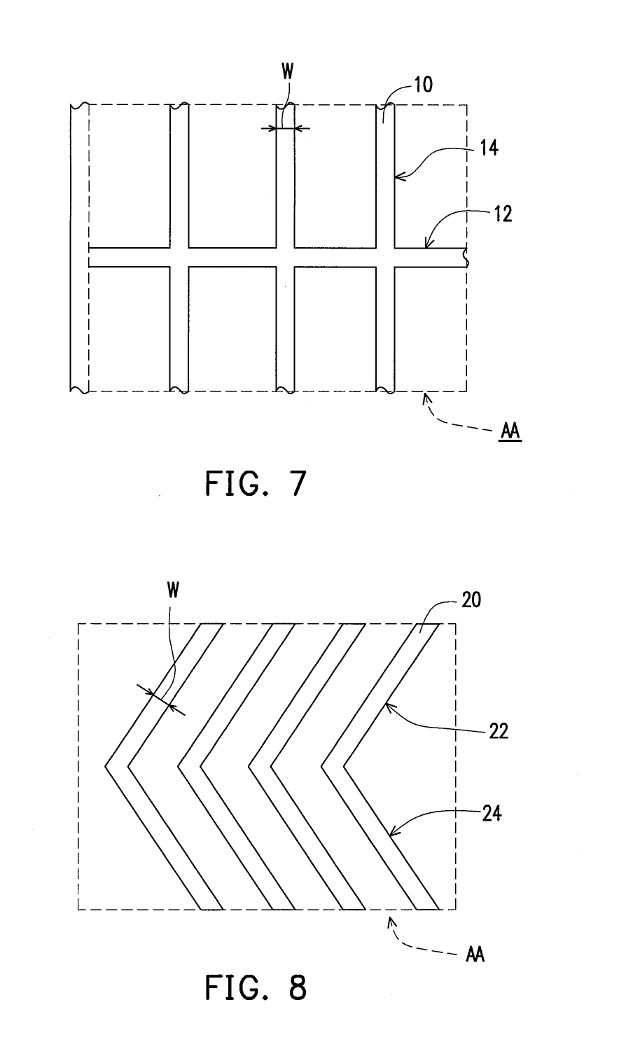

FIG. 7 is a schematic diagram illustrating a layout of the auxiliary conductive pattern layer according to an embodiment of the invention. Referring to FIG. 7, the auxiliary conductive pattern layer 10 can be formed by a plurality of linear patterns. In the present embodiment, the linear patterns are respectively a straight line and are connected to form a mesh. Nevertheless, the linear patterns constructing the auxiliary conductive pattern layer 10 can be zigzag lines, arc lines, curve lines, or other suitable patterns.

As to the embodiment, the auxiliary conductive pattern layer 120 forms a mesh and defines a plurality of rectangle openings with substantially identical size, wherein each rectangle opening has the lengths 12 and 14 extending in different directions. The shapes of the openings are not limited herein and can be other shapes, such as circles, oval shapes, polygons, or irregular shapes, based on the design of the linear patterns. As to the present embodiment, the perimeter (or namely circumference) of the auxiliary conductive pattern layer 10 occupied in the illumination region AA is a sum of 14 times of the length 12 and 8 times of the length 14. Namely, the perimeter (μm) of the auxiliary conductive pattern layer 10 occupied in the illumination region AA can be served as the total boundary length (μm) of the auxiliary conductive pattern layer 10 occupied in the illumination region AA. In addition, the ratio of the perimeter (μm) of the auxiliary conductive pattern layer 10 occupied in the illumination region AA to the area (μm²) of the illumination region AA is served as a reference in the present embodiment, wherein the ratio (R)=the perimeter (μm) of the auxiliary conductive pattern layer 10 occupied in the illumination region AA/the area (μm²) of the illumination region AA and the ratio (R) is adjusted for achieving the required light emitting effect in the embodiment, where unit of the ratio (R) is (1/μm).

Specifically, according to the measurement on the light emitting brightness of the illumination device configured with the auxiliary conductive pattern layer 10, the light emitting effect can have an enhancement ratio of about 1.45 by the configuration of the light extraction layer when the ratio (R) is at about 0.0063 (unit: 1/μm). The light emitting effect of the illumination device can have an enhancement ratio of about 1.3 by the configuration of the light extraction layer when the ratio (R) is at about 0.0063 (unit: 1/μm). The light emitting effect of the illumination device can have an enhancement ratio of about 1.12 by the configuration of the light extraction layer when the ratio (R) is at about 0.0023 (unit: 1/μm). Deriving from the measured results, the illumination device configured with the light extraction layer can have enhanced light emitting efficiency (i.e. the enhancement ratio is substantially greater than 1) and the electric current transmission of the conductive layer can be improved if the ratio (R) is substantially greater than 0 and about smaller than or substantially equal to 0.0262 (unit: 1/μm). Accordingly, the shape and the layout of the patterns of the auxiliary conductive pattern layer 10 can be properly designed to satisfy the ratio substantially greater than 0 and substantially smaller than or substantially equal to 0.0262 (unit: 1/μm) in the present embodiment.

It is noted that for avoiding the linear patterns from being seen owing to the large line width W thereof, the linear patterns constructing the auxiliary conductive pattern layer 10 according to the present embodiment have, for example, the line with W substantially greater than 0 μm and substantially smaller than or substantially equal to 60 μm. However, the values are exemplarily provided and the design and the line width W can be different because of the material, the size, the application of the illumination device. That is, the values mentioned in above have no intents to limit the scope of the disclosure. Based on those values, the light emitting efficiency of the illumination device can be improved when the ratio of the perimeter (μm) of the auxiliary conductive pattern layer 10 occupied in the illumination region AA to the area (μm²) of the illumination region AA is substantially greater than 0 and substantially smaller than or substantially equal to 0.0262 (1/μm). Particularly, the light extraction efficiency and the light emitting uniformity of the illumination device can satisfy the design requirement if the ratio (R) is equal to about 0.22 (1/μm).

It is noted that the layout of the auxiliary conductive pattern layer is not restricted to form a mesh and other embodiments are further provided in the following descriptions for illustrating purpose. FIG. 8 through FIG. 10 is respectively a schematic diagram illustrating a type of the layout of the auxiliary conductive pattern layer inside the illumination region. Referring to FIG. 8, the auxiliary conductive pattern layer 20 can include a plurality of zigzag linear patterns, wherein each linear pattern has the boundary lengths 22 and the boundary lengths 24 extending in different directions. As to the present embodiment, the perimeter of the auxiliary conductive pattern layer 20 occupied in the illumination region AA can be obtained by calculating the sum of the boundary lengths 22 and the boundary lengths 24 of these linear patterns. For avoiding the consciousness of the auxiliary conductive pattern layer 20 by the human eyes, the line width W of the linear patterns can be substantially greater than 0 μm and substantially smaller than or substantially equal to 60 μm.

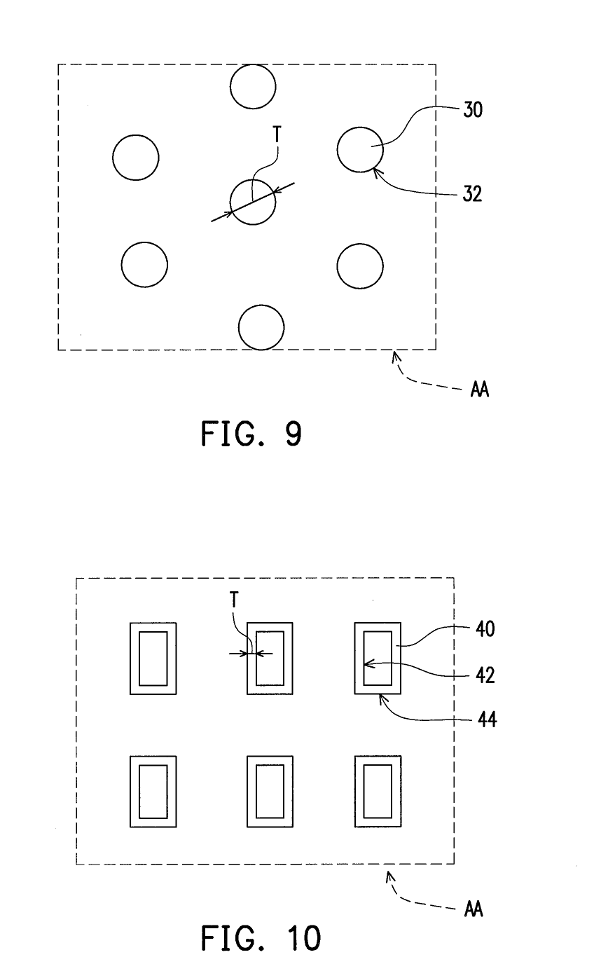

Referring to FIG. 9, the auxiliary conductive pattern layer 30 can be formed by a plurality of block patterns separated from each other. Herein, the shape of each block pattern can be a circle so that the perimeter of the auxiliary conductive pattern layer 30 occupied in the illumination region AA can be the sum of the circumferences 32 of the block patterns. It is noted that the block patterns separated from each other can have other shapes such as triangles, rectangles, hexagons, octagons, wavy shapes, etc. For avoiding the consciousness of the auxiliary conductive pattern layer 30 by the human eyes and maintaining enough light emitting area, the largest diameter T of each block pattern can be substantially greater than 0 μm and substantially smaller than or substantially equal to 60 μm. Herein, if the largest diameter T of the pattern is substantially greater than 60 μm, the human eyes can see the auxiliary conductive pattern layer 30, which means that the light emitting area is simultaneously reduced.

In an alternate embodiment, the block pattern is not restricted to be a solid pattern. Referring to FIG. 10, the auxiliary conductive pattern layer 40 can be formed by a plurality of hollow patterns. As to the present embodiment, the perimeter of the auxiliary conductive pattern layer 40 occupied in the illumination region AA is a sum of the inner diameters 42 and the outer diameters 44 of these hollow patterns. The hollow rectangle patterns illustrated in FIG. 10 are merely examples and the hollow patterns constructing the auxiliary conductive pattern layer 40 can have the shapes such as circles, oval shapes, polygons, irregular shapes, or other shapes. Alternately, the inner diameter 42 and the outer diameter 44 of the hollow patterns constructing the auxiliary conductive pattern layer 40 can form different shapes. For example, each hollow pattern of the auxiliary conductive pattern layer 40 can have a circle outer diameter and a rectangle inner diameter or have a circle inner diameter and a rectangle outer diameter. For avoiding the consciousness of the auxiliary conductive pattern layer 40 by the human eyes and maintaining enough light emitting area, the largest diameter T, such as the width, of each block pattern can be substantially greater than 0 μm and substantially smaller than or substantially equal to 60 μm. Herein, if the largest diameter T of the pattern is substantially greater than 60 μm, the human eyes can see the auxiliary conductive pattern layer 40, which means that the light emitting area is simultaneously reduced.

It is noted that the auxiliary conductive pattern layer 10, 20, 30, or 40 is evenly distributed in the illumination region AA, but the invention is not limited thereto. Specifically, in the illumination device, the distribution density of the auxiliary conductive pattern layer 10, 20, 30, or 40 in the illumination region AA can be adjusted when the impedance of the conductive layer is unevenly distributed for rendering the voltage of the conductive layer evenly distributed in the illumination region AA. For example, the distribution density of the auxiliary conductive pattern layer 10, 20, 30, or 40 can be increased in the region where the conductive layer has higher impedance and the distribution density of the auxiliary conductive pattern layer 10, 20, 30, or 40 can be decreased in the region where the conductive layer has lower impedance.

As shown in FIG. 1 through FIG. 5, during the illumination devices 100˜500 emit the light, energy such as the electric current passing through the self-illuminating layer 140 flows into or out of the first conductive layer 120 through the first electrode 122. Similarly, the electric current passing through the self-illuminating layer 140 flows into or out of the second conductive layer 130 through the second electrode 132. Now, as shown in FIG. 1, the energy such as the electric current flowing to a portion of the first conductive layer 120 relatively farther from the first electrode 122 is transmitted by a longer path in the first conductive layer 120 and can be obviously influenced by the impedance of the first conductive layer 120. Therefore, in one embodiment, the distribution density of the first auxiliary conductive pattern layer 150 can be gradually increased outward from the first electrode 122. Similarly, the distribution density of the second auxiliary conductive pattern layer 180 depicted in FIG. 5 can be gradually increased outward from the second electrode 132. As a whole, the first auxiliary conductive pattern layer 150 and the second auxiliary conductive pattern layer 180 are not limited to be distributed evenly in the invention and can be arranged in specific distribution density based on the factual requirement and the characteristics of the first auxiliary conductive pattern layer 150 and the second auxiliary conductive pattern layer 180.

In light of the foregoing, the auxiliary conductive pattern layer is in contact with the conductive layer according to the invention to improve the electric current transmission of the conductive layer. Accordingly, the illumination device has uniformed light emitting effect when the illumination area (i.e. the area of the illumination region) is enlarged. In addition, the auxiliary conductive pattern layer of the invention can be arranged in certain particular layout. 1. The auxiliary conductive pattern layer is disposed between the first surface (or namely the inner surface) of the substrate and the first conductive layer as shown in FIG. 1, or between the first conductive layer and the self illuminating layer as shown in FIG. 2. Herein, the light extraction film can be disposed on the second surface (or namely the outer surface) of the substrate and the first conductive layer can be made of the transparent conductive material. 2. The auxiliary conductive pattern layer is disposed between the first surface (or namely the inner surface) of the protection material and the first conductive layer as shown in FIG. 3, or between the first conductive layer and the self-illuminating layer as shown in FIG. 4. Herein, the light extraction film can be disposed on the second surface (or namely the outer surface) of the protection material and the first conductive layer can be made of the transparent conductive material. 3. The auxiliary conductive pattern layers are disposed between the first surface (or namely the inner surface) of the substrate and the first conductive layer and between the first surface (or namely the inner surface) of the protection material and the second conductive layer and the first and the second conductive layers are made of the transparent conductive material. The light extraction films can be disposed on both the second surface (or namely the outer surface) of the substrate and the second surface (or namely the outer surface) of the protection material. 4. The auxiliary conductive pattern layers are disposed between the first surface (or namely the inner surface) of the substrate and the first conductive layer and between the second conductive layer and the self-illuminating layer and the first and the second conductive layers are made of the transparent conductive material. The light extraction films can be disposed on both the second surface (or namely the outer surface) of the substrate and the second surface (or namely the outer surface) of the protection material. 5. The auxiliary conductive pattern layers are disposed between the first conductive layer and the self-illuminating layer and between the first surface (or namely the inner surface) of the protection material and the second conductive layer and the first and the second conductive layers are made of the transparent conductive material. The light extraction films can be disposed on both the second surface (or namely the outer surface) of the substrate and the second surface (or namely the outer surface) of the protection material. 6. The auxiliary conductive pattern layers are disposed between the first conductive layer and the self-illuminating layer and between the second conductive layer and the self-illuminating layer and the first and the second conductive layers are made of the transparent conductive material. The light extraction films can be disposed on both the second surface (or namely the outer surface) of the substrate and the second surface (or namely the outer surface) of the protection material and located at the illumination region for improving the light extraction efficiency of the illumination device. Among the abovementioned examples, the third to the sixth layouts of the disclosure can be referred to the detail descriptions and the relative variants as shown in FIG. 5.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An illumination device comprising:
a substrate;
a first conductive layer disposed on the substrate;
a second conductive layer disposed on the substrate;
a self-illuminating layer disposed between the first conductive layer and the second conductive layer to define an illumination region on the substrate; and
a first auxiliary conductive pattern layer in contact with the first conductive layer, an impedance of the first auxiliary conductive pattern layer being smaller than an impedance of the first conductive layer, and a ratio of a perimeter (um) of the first auxiliary conductive pattern layer occupied in the illumination region to an area (um²) of the illumination region being greater than 0 and smaller than or equal to 0.0262 (1/um).

2. The illumination device of claim 1, wherein the first auxiliary conductive pattern layer is located at a side of the first conductive layer adjacent to the self-illuminating layer.

3. The illumination device of claim 1, wherein the first auxiliary conductive pattern layer is located at a side of the first conductive layer away from the self-illuminating layer.

4. The illumination device of claim 1, wherein the first auxiliary conductive pattern layer comprises a plurality of strip patterns.

5. The illumination device of claim 4, wherein the stripe patterns are connected to form a mesh.

6. The illumination device of claim 1, wherein the first auxiliary conductive pattern layer comprises a plurality of block patterns separated from each other.

7. The illumination device of claim 1, wherein the ratio of the perimeter (um) of the first auxiliary conductive pattern layer occupied in the illumination region to the area (um²) of the illumination region is substantially equal to 0.022 (1/um).

8. The illumination device of claim 1, further comprising a second auxiliary conductive pattern layer in contact with the second conductive layer, wherein an impedance of the second auxiliary conductive layer is smaller than an impedance of the second conductive layer.

9. The illumination device of claim 8, wherein a ratio of a perimeter (um) of the second auxiliary conductive pattern layer occupied in the illumination region to the area (um²) of the illumination region is greater than 0 and smaller than or equal to 0.0262 (1/um).

10. The illumination device of claim 8, wherein the second auxiliary conductive pattern layer comprises a plurality of strip patterns.

11. The illumination device of claim 10, wherein the stripe patterns are connected to form a mesh.

12. The illumination device of claim 8, wherein the second auxiliary conductive pattern layer comprises a plurality of block patterns separated from each other.

13. The illumination device of claim 8, wherein the ratio of the perimeter (um) of the second auxiliary conductive pattern layer occupied in the illumination region to the area (um²) of the illumination region is substantially equal to 0.022 (1/um).

14. The illumination device of claim 1, wherein a material of the self-illuminating layer comprises an organic light-emitting material.

15. The illumination device of claim 1, further comprising a light extraction layer disposed at a side of the substrate away from the self-illuminating layer.

16. The illumination device of claim 1, further comprising a protection material, wherein the first conductive layer, the self-illuminating layer, and the second conductive layer are located between the protection material and the substrate.
